(19) United States
(12) Patent Application Publication
(10) Pub. No.: US 2008/0232416 A1
(43) Pub. Date: Sep. 25, 2008

(54) Light emitting device

(75) Inventors: Kuniyoshi Okamoto, Kyoto-shi (JP); Hiroaki Ohta, Kyoto-shi (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/076,762

(22) Filed: Mar. 21, 2008

(30) Foreign Application Priority Data
Mar. 23, 2007 (JP) 2007-077035

(51) Int. Cl. H01S 5/32

(52) U.S. Cl. 372/45.01

(57) ABSTRACT

A light emitting device includes a nitride semiconductor light emitting element provided with a group III nitride semiconductor laminating structure and a laser. The group III nitride semiconductor laminating structure has a non-polar plane or a semi-polar plane as a principal plane for crystal growth and includes a multiple-quantum well layer having a quantum well layer as an emission layer containing In and a barrier layer having a wider band gap than that of the quantum well layer. The laser generates induced emission light having a wavelength shorter than an emission wavelength of the quantum well layer and optically excites the quantum well layer in the nitride semiconductor light emitting element with the induced emission light.

### BACKGROUND OF THE INVENTION

1. Field of the Invention

The present invention relates to a light emitting device using a nitride semiconductor.

2. Description of Related Art

Of the group III-V semiconductors, semiconductors using nitrogen as group V elements are referred to as group III nitride semiconductors. Representative examples are aluminum nitride (AlN), gallium nitride (GaN), and indium nitride (InN). Generally, they are expressed as AlₓIn_{y}Ga_{l-x-y}N, where 0≦x≦1, 0≦y≦1, and 0≦x+y≦1.

A manufacturing method of a nitride semiconductor was been known to grow a group III nitride semiconductor on a gallium nitride (GaN) substrate having the principal plane in the c-plane by metalorganic chemical vapor deposition (MOCVD). By adopting this method, it is possible to form a group III nitride semiconductor laminating structure having an n-type layer and a p-type layer to fabricate a light emitting device using this laminating structure.

When an active layer (emission layer) having an emission wavelength of 500 nm or longer is formed from a group III nitride semiconductor, it is known that such an active layer is vulnerable to heat damage. To be more concrete, for instance, a case will be described as an example where a light emitting diode structure is formed by growing an n-type GaN semiconductor layer on a GaN substrate to laminate an active layer made of a group III nitride semiconductor thereon and by further growing a p-type GaN semiconductor layer on the active layer. In this case, in order to achieve an emission wavelength of 500 nm or longer, it is necessary that In (indium) is taken into the active layer. To this end, the substrate temperature while the active layer is grown is set at 700° C. to 800° C. The substrate temperature, on the other hand, is set at 800° C. or higher when the p-type GaN layer is epitaxially grown on the active layer. The active layer undergoes heat damage in this instance, and emission efficiency is impaired significantly. It is therefore by no means easy to obtain light having a long wavelength of 500 nm or longer.

### SUMMARY OF THE INVENTION

An object of the invention is to provide a light emitting device that can achieve emission of light having a long wavelength using a group III nitride semiconductor.

A light emitting device of the invention includes a nitride semiconductor light emitting element provided with a group III nitride semiconductor laminating structure and a laser. The group III nitride semiconductor laminating structure has a non-polar plane or a semi-polar plane as a principal plane for crystal growth and includes a multiple-quantum well layer having a quantum well layer as an emission layer containing in and a barrier layer having a wider band gap than that of the quantum well layer. Examples of the non-polar plane include m-plane (10-10) and a-plane (11-20). Examples of the semi-polar plane include (10-1-1) plane, (10-1-3) plane, and (11-22) plane. The laser generates induced emission light having a wavelength shorter than an emission wavelength of the quantum well layer and optically excites the quantum well layer in the nitride semiconductor light emitting element with the induced emission light.

According to this configuration, by incidence of induced emission light having a short wavelength from the laser on the nitride semiconductor light emitting element, it is possible to optically excite the quantum well layer forming the multiple-quantum well layer in the nitride semiconductor light emitting element. It is thus possible to generate light having a long wavelength from the nitride semiconductor light emitting element. Hence, because there is no need to electrically excite the quantum well layer, the nitride semiconductor light emitting element does not need to be provided with a light emitting diode structure. Accordingly, there is no need to form another layer (for example, a p-type semiconductor layer) that needs a treatment at such a high temperature that causes heat damage to the multiple-quantum well layer after the multiple-quantum well layer is formed. Consequently, the multiple-quantum well layer can emit light having a long wavelength at high efficiency.

In addition, because the group III nitride semiconductor laminating structure uses a non-polar plane or a semi-polar plane (that is, a plane other than c-plane) as the principal plane for crystal growth, it is possible to grow crystals in an extremely stable manner. Hence, in comparison with a case where c-plane is used as the principal plane for crystal growth, the crystalline property can be enhanced. It is thus possible to upgrade the quality of the group III nitride semiconductor laminating structure to consequently enhance emission efficiency.

Further, by using a group III nitride semiconductor having a non-polar plane or a semi-polar plane which is a different material from c-plane group III nitride semiconductor, it is possible to suppress separation of carriers due to spontaneous piezoelectric polarization in the quantum well layer. Therefore, emission efficiency is increased. Moreover, the current dependency of an emission wavelength is suppressed owing to the absence of the separation of carriers by the spontaneous piezoelectric polarization. It is thus possible to achieve a stable emission wavelength.

Further, light extracted from the emission layer made of the group III nitride semiconductor having the principal plane for growth in c-plane is in a random polarized (non-polarized) state. In contrast, the emission layer formed using the group III nitride semiconductor having a non-polar plane or a semi-polar plane as the principal plane for growth is able to emit light in a strong polarized state. By exploiting this, it is possible to apply the light emitting device of the invention as a light source for a device that performs control using polarized light, such as a liquid crystal display panel. The light emitting device of the invention is also applicable to optical measurement that needs polarized light having a long wavelength.

The laser may be a semiconductor laser made of a group III nitride semiconductor. Because the semiconductor laser merely needs to generate induced emission light having a short wavelength, even in a case where the laser is made of group III nitride semiconductor, the emission layer has durability against heat damage. There is no need for the nitride semiconductor light emitting element that is optically excited by the induced emission light from the semiconductor laser to have the light emitting diode structure. Accordingly, even an emission layer for a long wavelength can be manufactured without undergoing heat damage. It is thus possible to form a light emitting device capable of emitting light having a long wavelength at high emission efficiency using nitride semiconductor.

For example, the emission wavelength of the quantum well layer may be 500 nm to 650 nm, and the emission wavelength of the laser may be 300 nm to 450 nm. Light having a wavelength of 300 nm to 450 nm can efficiently excite constitutive layers (for example, a GaN layer and an InGaN layer) of the multiple-quantum well layer. In addition, by setting the emission wavelength of the quantum well layer to 500 nm to 650 nm, it is possible to obtain polarized light in a wavelength range showing green to red.

In addition, the multiple-quantum well layer may include not less than five quantum well layers. When configured in this manner, it is possible to increase an absorption ratio of exciting light.

Further, it is preferable that a normal direction to a principal plane of the multiple-quantum well layer and a laser beam emission direction of the laser are non-parallel. According to this configuration, it is possible to selectively extract only the light from the nitride semiconductor light emitting element.

Other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic perspective view describing the configuration of a light emitting device according to one embodiment of the invention.

FIG. 2 is a schematic cross section describing the structure of a nitride semiconductor light emitting element according to one embodiment of the invention.

FIG. 3 is a schematic view showing a unit cell in the crystal structure of group III nitride semiconductor.

FIG. 4 is a schematic view describing the configuration of a processing apparatus for growing respective layers that form a GaN semiconductor layer.

### DETAILED DESCRIPTION OF THE PREFERRED EMBODIMENTS

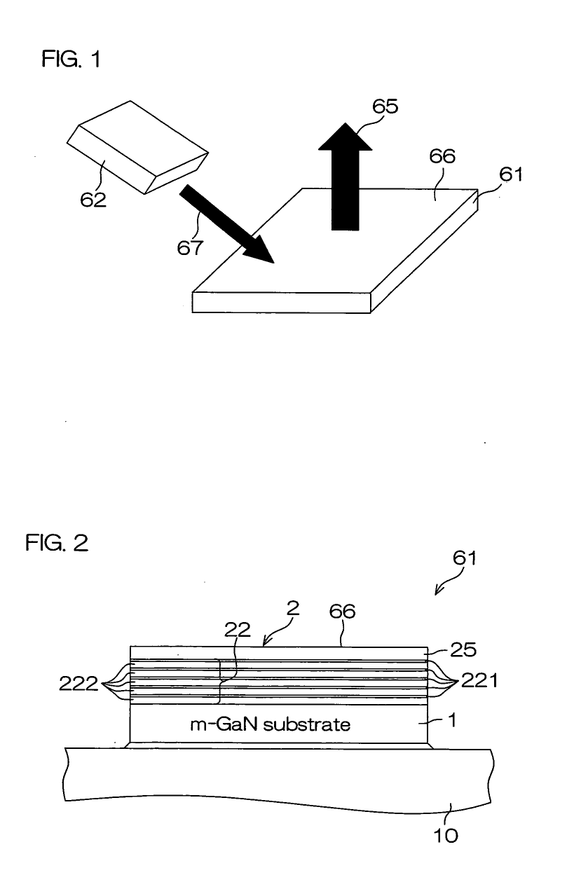

FIG. 1 is a schematic perspective view describing the configuration of a light emitting device according to one embodiment of the invention. The light emitting device includes a nitride semiconductor light emitting element 61 and a semiconductor laser 62.

The nitride semiconductor light emitting element 61 is made of a group III nitride semiconductor and generates light having a long wavelength of 500 nm or longer (for example, 532 nm). In this embodiment, the nitride semiconductor light emitting element 61 is configured to emit polarized light 65 to the exterior from a light extracting surface 66.

The semiconductor laser 62 is made of a group III nitride semiconductor, and generates a laser beam 67 (induced emission light) having a shorter wavelength (less than 450 nm, for example, 405 nm) than the emission wavelength of the nitride semiconductor light emitting element 61. To be more concrete, the semiconductor laser 62 is, for example, a known Fabry-Perot laser having an n-type clad layer (for example, an AlGaN layer), an emission layer having a multiple-quantum well structure (for example, a structure including InGaN), and a p-type clad layer (for example, an AlGaN layer).

The semiconductor laser 62 is disposed such that the laser beam 67 is incident on the nitride semiconductor light emitting element 61. In this embodiment, the laser beam 67 is adapted to be incident on the nitride semiconductor light emitting element 61 so that the laser beam emission direction of the semiconductor laser 62 is inclined with respect to the normal direction to the light extracting surface 66 of the nitride semiconductor light emitting element 61.

According to this configuration, when the laser beam 67 having a short wavelength is generated by driving the semiconductor laser 62, the laser beam 67 is incident on the nitride semiconductor light emitting element 61. Upon receipt of the laser beam 67, light excitation takes place on the active layer (emission layer) in the nitride semiconductor light emitting element 61, and light having a long wavelength that is generated by the light excitation is emitted from the light extracting surface 66 as polarized light 65. By driving the short wavelength semiconductor laser 62 with a supply of power in this manner, the nitride semiconductor light emitting element 61 generates the polarized light 65 by light excitation without a supply of power (that is, not by current excitation). The nitride semiconductor light emitting element 61 therefore does not need to be provided with a diode structure for current excitation. In addition, because the direction of incidence of the laser beam 67 is deviated from the normal direction to the light extracting surface 66, it is possible to selectively extract only the light emitted from the nitride semiconductor light emitting element 61.

FIG. 2 is a schematic cross section describing an example of the structure of the nitride semiconductor light emitting element 61. The nitride semiconductor light emitting element is formed by growing a group III nitride semiconductor layer 2 that forms the group III nitride semiconductor laminating structure on a GaN (gallium nitride) substrate 1, which is one example of a group III nitride semiconductor substrate.

The group III nitride semiconductor layer 2 includes a multiple-quantum well (MQW) layer 22 as an active layer (emission layer) formed on the GaN substrate 1. The GaN substrate 1 is joined to a support substrate (wiring board) 10. The group III nitride semiconductor layer 2 is sealed with transparent resin, such as epoxy resin, when necessary. The surface of the group III nitride semiconductor layer 2 is the light extracting surface 66.

The multiple-quantum well layer 22 is formed by laminating a quantum well layer 221 and a barrier layer 222 having a wider band gap than that of the quantum well layer 221 alternately in predetermined cycles (preferably, five cycles or more). To be more concrete, the multiple-quantum well layer 22 is formed by laminating a silicon-doped InGaN layer (quantum well layer 221, for example, having a thickness of 3 nm) and a non-doped GaN layer (barrier layer 222, for example, having a thickness of 9 nm) alternately in predetermined cycles (for example, five cycles). A GaN final barrier layer 25 (for example, having a thickness of 40 nm) is laminated on the multiple-quantum well layer 22. No other layer, such as a p-type contact layer, is formed on the final barrier layer 25.

The emission wavelength of the multiple-quantum well layer 22 is set to 500 nm or longer. To be more concrete, it is set, for example, to 500 nm to 650 nm (a wavelength band from green to red). The emission wavelength corresponds to the band gap of the quantum well layer 221, and the band gap can be adjusted by adjusting a composition ratio of indium (In). As the composition ratio of indium is increased, the band gap becomes smaller and the emission wavelength becomes longer.

There is no need to equalize the emission wavelengths of all the quantum well layers 221 included in the multiple-quantum well layer 22. In short, the multiple-quantum well layer 22 may include plural quantum well layers 221 having different emission wavelengths. In this case, light having more than one peak wavelength is generated and the resulting mixed color is observed.

The GaN substrate 1 is a substrate made of GaN having the principal plane in a plane other than c-plane. To be more concrete, it has a non-polar plane or a semi-polar plane as the principal plane (in the example of FIG. 2, m-plane is the principal plane). The GaN substrate 1 is preferably a GaN single crystalline substrate having the principal plane in a plane having an off angle within ±1° from the plane orientation of a non-polar plane or in a plane having an off angle within ±1° from the plane orientation of a semi-polar plane. The principal plane for lamination (principal plane for crystal growth) of each layer in the group III nitride semiconductor layer 2 follows the crystal plane of the principal plane of the GaN substrate 1. In short, each of the principal planes of the layers forming the group III nitride semiconductor layer 2 has the same crystal plane as the crystal plane of the principal plane of the GaN substrate 1. Because the principal plane of the GaN substrate 1 is a specific crystal plane (non-polar plane or semi-polar plane) other than c-plane, the principal plane of the multiple-quantum well layer 22 is also a crystal plane (the same crystal plane as the GaN substrate 1) other than c-plane. The multiple-quantum well layer 22 therefore emits polarized light.

When the laser light 67 from the semiconductor laser 62 is incident on the nitride semiconductor light emitting element 61, the polarized light 65 is generated due to light excitation in the multiple-quantum well layer 22, and the polarized light 65 is extracted from the light extracting surface 66.

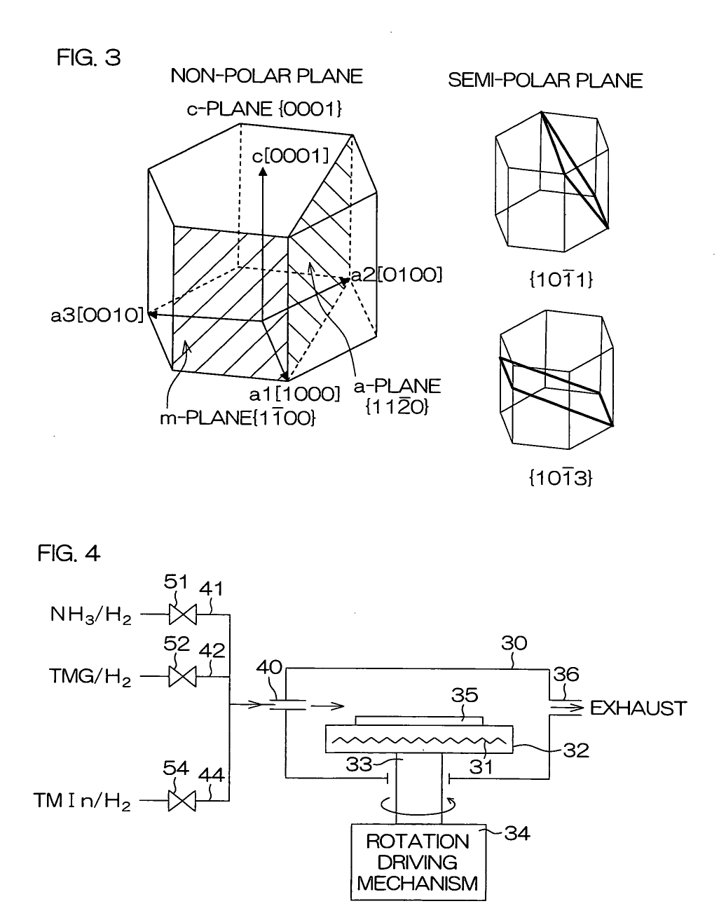

FIG. 3 is a schematic view showing a unit cell in the crystal structure of group III nitride semiconductor. The crystal structure of group III nitride semiconductor can be approximated by a hexagonal system. The plane (the top face of the hexagonal cylinder) having c-axis as the normal line of the hexagonal cylinder along the axial direction is c-plane (0001). In the group III nitride semiconductors, the polarization direction is along c-axis. Accordingly, c-plane shows different properties on the +c-axis side and on the −c-axis side, so that this plane is called a polar plane.

Meanwhile, each of the side faces of the hexagonal cylinder is m-plane (10-10), and a plane passing a pair of ridge lines that are not adjacent to each other is a-plane (11-20). Because these planes are crystal planes at right angles with respect to c-plane and orthogonal to the polarization direction, they are planes having no polarity, that is, non-polar planes. Further, because crystal planes that incline with respect to c-plane (neither parallel to nor at right angles with c-plane) crosses slantwise the polarization direction, they are planes having slight polarization, that is, semi-polar planes.

Concrete examples of the semiconductor planes include (10-1-1) plane, (10-1-3) plane, and (11-22) plane.

T. Takeuchi et al., Jap. J. Appl. Phys. 39, 413-416, 2000 shows the relation between the off angle of the crystal plane with respect to c-plane and the polarization in the normal direction to the crystal plane. From this reference document, it can be said that planes, such as (11-24) plane and (10-12) plane, are also crystal planes having less polarization and they are therefore important crystal planes having the potentiality of being adopted in order to extract light in a significant polarized state.

For example, a GaN single crystalline substrate having the principal plane in m-plane can be manufactured by cutting out from a GaN single crystal having the principal plane in c-plane. The m-plane of the cut-out substrate is polished, for example, by chemical and mechanical polishing until an azimuth error with respect to both the (0001) direction and the (11-20) direction falls within ±1° (preferably within ±0.3°). A GaN single crystalline substrate having the principal plane in m-plane and no crystal defects, such as dislocation and stacking fault, can be thus obtained. Steps merely at the atomic level are present on the surface of such a GaN single crystalline substrate.

The group III nitride semiconductor layer 2 is grown on the GaN single crystalline substrate obtained as above by metalorganic chemical vapor deposition.

The group III nitride semiconductor layer 2 having the principal plane for growth in m-plane is grown on the GaN single crystalline substrate 1 having the principal plane in m-plane and the cross section along a-plane is observed using a scanning transmission electron microscope (STEM). Then, a striation indicating the presence of dislocation is not seen in the group III nitride semiconductor layer 2. Further, an observation of the surface state using an optical microscope reveals that the flatness (a difference in height between the end portion and the bottom portion) in c-axis direction is 10 Å or less. This means that the flatness in c-axis direction of the multiple-quantum well layer 22, in particular, the quantum well layer 221, is 10 Å or less. Accordingly, the half bandwidth of an emission spectrum can be reduced.

As has been described, it is possible to grow an m-plane group III nitride semiconductor having no dislocation and a flat lamination interface. However, the off angle of the principal plane of the GaN single crystalline substrate 1 preferably falls within ±1° (more preferably +0.3°). For example, when a group III nitride semiconductor layer is grown on an m-plane GaN single crystalline substrate having the off angle of 2°, group III nitride semiconductor crystals are grown in the shape of a terrace, and a surface state as flat as that obtained in the case of setting the off angle within ±1° may not be obtained.

Because the group III nitride semiconductor grown by crystal growth is grown on the GaN single crystalline substrate having the principal plane in m-plane, the group III nitride semiconductor is to have the principal plane for growth in m-plane. In a case where it is grown by crystal growth having the principal plane in c-plane, emission efficiency in the quantum well layer 221 may possibly be deteriorated because of influences of polarization in the c-axis direction. On the contrary, in a case where it is grown having the principal plane for crystal growth in m-plane, polarization in the quantum well layer 221 is suppressed and emission efficiency can be therefore increased. In addition, because the polarization is small, the current dependency of the emission wavelength is suppressed. It is thus possible to achieve a stable emission wavelength.

Further, the crystal growth of the group III nitride semiconductor can be performed in an extremely stable manner using a non-polar plane as the principal plane for crystal growth. Therefore, in comparison with a case where c-plane is the principal plane for crystal growth, the crystalline property of the group III nitride semiconductor layer 2 can be enhanced. Emission at high efficiency is thus enabled. In particular, by using m-plane as the principal plane for crystal growth, it is possible to enhance the crystalline property of the group III nitride semiconductor layer 2 in comparison with a case where a-plane is the principal plane for crystal growth.

Furthermore, in this embodiment, because a GaN single crystalline substrate is used as the substrate 1, the group III nitride semiconductor layer 2 can have a high crystalline quality with fewer defects. It is thus possible to achieve a high-performance light emitting element.

Further, by growing the group III nitride semiconductor layer 2 on the GaN single crystalline substrate having substantially no dislocation, the group III nitride semiconductor layer 2 can be satisfactory crystals having no stacking fault or threading dislocation from the grown surface (m-plane) of the substrate 1. It is thus possible to suppress characteristic deterioration, such as defect-induced deterioration in emission efficiency.

FIG. 4 is a schematic view describing the configuration of a processing apparatus to grow the group III nitride semiconductor layer 2. A susceptor 32 enclosing a heater 31 is installed in a process chamber 30. The susceptor 32 is coupled to a rotating shaft 33, and the rotating shaft 33 is rotated by a rotation driving mechanism 34 provided in the exterior of the process chamber 30. Accordingly, by holding a wafer 35 to be processed with the susceptor 32, it is possible to heat the wafer 35 to a specific temperature, and to rotate the wafer 35 inside the process chamber 30. The wafer 35 is, for example, a GaN single crystalline wafer that forms the GaN substrate 1 described above.

An exhaust pipe 36 is connected to the process chamber 30. The exhaust pipe 36 is connected to an exhaust system, such as a rotary pump. Accordingly, the pressure inside the process chamber 30 is maintained at 1/10 atmospheric pressure to normal pressure (preferably, about ⅕ atmospheric pressure), and the atmosphere inside the process chamber 30 is exhausted constantly.

A raw material gas supply channel 40 for supplying raw material gases toward the surface of the wafer 35 held by the susceptor 32 is introduced into the process chamber 30. A nitrogen raw material pipe 41 for supplying ammonia as a nitrogen raw material gas, a gallium raw material pipe 42 for supplying trimethyl gallium (TMG) as a gallium raw material gas, and an indium raw material pipe 44 for supplying a trimethyl indium (TMIn) as an indium raw material gas are connected to the raw material gas supply channel 40. Valves 51, 52, and 54 are interposed in these raw material pipes 41, 42, and 44, respectively. Each raw material gas is supplied together with a carrier gas of hydrogen or nitrogen or both.

For example, a GaN single crystalline wafer having the principal plane in m-plane is held by the susceptor 32 as the wafer 35. In this state, a carrier gas and an ammonia gas (nitrogen raw material gas) are supplied inside the process chamber 30 by opening the nitrogen raw material valve 51 while keeping the valves 52 and 54 closed. Further, the heater 31 is energized and the wafer temperature is raised to 1000° C. to 1100° C. (for example, 1050° C.). It is thus possible to grow a GaN semiconductor without causing any roughness on the surface.

After the sequence waits until the wafer temperature reaches 1000° C. to 1100° C., the multiple-quantum well layer 22 is grown. The multiple-quantum well layer 22 is grown by alternately performing a step of growing an additive-free GaN layer (barrier layer) by supplying ammonia and trimethyl gallium to the wafer 35 by closing the indium raw material valve 54 and opening the nitrogen raw material valve 51 and the gallium raw material valve 52, and a step of growing an InGaN layer (quantum well layer) by supplying ammonia, trimethyl gallium, and trimethyl indium to the wafer 35 by opening the nitrogen raw material valve 51, the gallium raw material valve 52, and the indium raw material valve 54. For example, the GaN layer is formed first, and the InGaN layer is formed thereon. After these steps are performed repetitively five times, the GaN final barrier layer 25 is formed on the uppermost InGaN layer. While the multiple-quantum well layer 22 and the GaN final barrier layer 25 are formed, it is preferable that the temperature of the wafer 35 is maintained at 700° C. to 800° C. (less than 800° C., for example, 730° C.)

After the wafer process as described above, individual elements are cut out by cleaving the wafer 35. Each of the individual elements is mounted on the support substrate 10 by die bonding, and then sealed with transparent resin, such as epoxy resin. The nitride semiconductor light emitting element 61 is thus fabricated.

Because it is unnecessary for the nitride semiconductor light emitting element 61 to have the light emitting diode structure, there is no need to form a p-type group III nitride semiconductor layer after the multiple-quantum well layer 22 is formed. In other words, the multiple-quantum well layer 22 is not subjected to high-temperatures (800° C. or higher, for example, 1000° C.) needed to form p-type group III nitride semiconductor layer. Hence, because the multiple-quantum well layer 22 does not undergo heat damage, the multiple-quantum well layer 22 can achieve excellent emission efficiency although it is an emission layer having a long emission wavelength. Meanwhile, the semiconductor laser 62 only needs to be provided with an emission layer having a short emission wavelength, and such an emission layer can withstand high temperatures needed to form p-type group III nitride semiconductor layer. The semiconductor laser 62 can therefore also achieve excellent emission efficiency. In this manner, it is possible to achieve a light emitting device capable of generating light in a long wavelength band (polarized light) at excellent emission efficiency.

While one embodiment of the invention has been described, the invention can be practiced in another embodiment. For example, the embodiment above chiefly described an example using the GaN substrate 1 having the principal plane in m-plane. However, a GaN substrate having the principal plane in a-plane may be used as well. Further, a GaN substrate that uses a semi-polar plane, such as (10-11) plane, (10-13) plane, and (11-22) plane, as the principal plane may be also used.

In addition, a case described above, the group III nitride semiconductor layer 2 is grown on the GaN substrate 1. However, for example, a group III nitride semiconductor having the principal plane for growth in m-plane may be grown on a silicon carbide substrate having the principal plane in m-plane or a group III nitride semiconductor having the principal plane in a-plane may be grown on a sapphire substrate having the principal plane in r-plane.

Further, the embodiment above describes a case where the group III nitride semiconductor is epitaxially grown on the GaN substrate 1 by MOCVD. However, another epitaxial growth method, such as hydride vapor phase epitaxy (HVPE), is also applicable.

The embodiment above describes a case where the semiconductor laser 62 made of a group III nitride semiconductor is used. However, it is sufficient for the semiconductor laser 62 to generate the laser beam 67 that can optically excite the multiple-quantum well layer 22 in the nitride semiconductor light emitting element 61, and it is not necessarily made of a group III nitride semiconductor. Further, it may be configured such that light excitation takes place on the multiple-quantum well layer 22 in the nitride semiconductor light emitting element 61 by adopting a laser using a laser medium (substance that causes induced emission) other than the semiconductor.

While the embodiments of the invention have been described in detail, it should be appreciated that these embodiments represent examples to provide clear understanding of the technical contents of the invention, and the invention is not limited to these examples. The spirit and the scope of the invention, therefore, are limited solely by the scope of the appended claims.

This application is based upon the prior Japanese Patent Application No. 2007-77035 filed with the Japanese Patent Office on Mar. 23, 2007, the entire disclosure of which is incorporated herein by reference.

What is claimed is:

1. A light emitting device, comprising:
a nitride semiconductor light emitting element provided with a group III nitride semiconductor laminating structure has a non-polar plane or a semi-polar plane as a principal plane for crystal growth and includes a multiple-quantum well layer having a quantum well layer as an emission layer containing In and a barrier layer having a wider band gap than that of the quantum well layer; and
a laser that generates induced emission light having a wavelength shorter than an emission wavelength of the quantum well layer and optically excites the quantum well layer in the nitride semiconductor light emitting element with the induced emission light.

2. The light emitting device according to claim 1, wherein the laser is a semiconductor laser made of a group III nitride semiconductor.

3. The light emitting device according to claim 1, wherein the emission wavelength of the quantum well layer is 500 nm to 650 nm, and the emission wavelength of the laser is 300 nm to 450 nm.

4. The light emitting device according to claim 2, wherein the emission wavelength of the quantum well layer is 500 nm to 650 nm, and the emission wavelength of the laser is 300 nm to 450 nm.

5. The light emitting device according to claim 1, wherein the multiple-quantum well layer includes not less than five quantum well layers.

6. The light emitting device according to claim 2, wherein the multiple-quantum well layer includes not less than five quantum well layers.

7. The light emitting device according to claim 3, wherein the multiple-quantum well layer includes not less than five quantum well layers.

8. The light emitting device according to claim 4, wherein the multiple-quantum well layer includes not less than five quantum well layers.

9. The light emitting device according to claim 1, wherein a normal direction to a principal plane of the multiple-quantum well layer and a laser beam emission direction of the laser are non-parallel.

10. The light emitting device according to claim 2, wherein a normal direction to a principal plane of the multiple-quantum well layer and a laser beam emission direction of the laser are non-parallel.

11. The light emitting device according to claim 3, wherein a normal direction to a principal plane of the multiple-quantum well layer and a laser beam emission direction of the laser are non-parallel.

12. The light emitting device according to claim 4, wherein a normal direction to a principal plane of the multiple-quantum well layer and a laser beam emission direction of the laser are non-parallel.

13. The light emitting device according to claim 5, wherein a normal direction to a principal plane of the multiple-quantum well layer and a laser beam emission direction of the laser are non-parallel.

14. The light emitting device according to claim 6, wherein a normal direction to a principal plane of the multiple-quantum well layer and a laser beam emission direction of the laser are non-parallel.

15. The light emitting device according to claim 7, wherein a normal direction to a principal plane of the multiple-quantum well layer and a laser beam emission direction of the laser are non-parallel.

16. The light emitting device according to claim 8, wherein a normal direction to a principal plane of the multiple-quantum well layer and a laser beam emission direction of the laser are non-parallel.
